(19) United States
(12) Patent Application Publication
(10) Pub. No.: US 2024/0017284 A1
(43) Pub. Date: Jan. 18, 2024

(54) APPARATUS FOR PROCESSING SUBSTRATE

(71) Applicant: SEMES CO., LTD., Chungcheongnam-do (KR)

(72) Inventors: Dae Sung KIM, Chungcheongnam-do (KR); Jae Hyun LIM, Chungcheongnam-do (KR); Kyo Sang YOON, Chungcheongnam-do (KR); Ho Jin JANG, Chungcheongnam-do (KR); A Rah CHO, Chungcheongnam-do (KR)

(21) Appl. No.: 18/138,038

(22) Filed: Apr. 22, 2023

(30) Foreign Application Priority Data
Jul. 15, 2022 (KR) 10-2022-0087731

(51) Int. Cl. B05C 9/08

(52) U.S. Cl. CPC B05C 9/08

(57) ABSTRACT

An apparatus for processing a substrate includes a processing vessel disposed in a process chamber and including a processing space in which a substrate is accommodated; a liquid supply line configured to process the substrate by supplying processing liquid to the substrate in the processing space; an exhaust line connected to the processing vessel and configured to exhaust gas in the processing space; a spraying portion disposed on the exhaust line and configured to spray cleaning liquid to remove contaminants accumulated in the exhaust line; and a washing liquid discharge line branched from the exhaust line and including a suction portion therein to suction cleaning liquid waste including contaminants removed from the exhaust line by the cleaning liquid and to discharge the cleaning liquid waste to the outside.

### CROSS-REFERENCE TO RELATED APPLICATIONS

The application claims benefit of priority to Korean Patent Application No. 10-2022-0087731 filed on Jul. 15, 2022 in the Korean Intellectual Property Office, the disclosure of which is incorporated herein by reference in its entirety.

### BACKGROUND

### 1. Field

Embodiments of the present disclosure relate to an apparatus for processing a substrate.

### 2. Description of Related Art

Generally, in a process of manufacturing a semiconductor, a substrate may be manufactured through a deposition process, an etching process, a photo process, and a cleaning process. For example, a photo process may be performed by spraying various types of processing liquids on a substrate using an apparatus for processing a substrate. Specifically, in a coating process, a solid photoresist may be dissolved in a solvent and may be supplied in a liquid state. During the coating process, the photoresist and solvent may be partially vaporized and may be discharged externally through an exhaust pipe formed on the bottom of a processing vessel. Contaminants (hereinafter, referred to as fumes) including the vaporized photoresist and solvent vapor may accumulate in the exhaust pipe as the contaminants may not be sufficiently discharged, and when the exhaust pipe is clogged, the substrate in the processing vessel may be contaminated.

### SUMMARY

An embodiment of the present disclosure is to provide an apparatus for processing a substrate which may effectively remove fumes accumulated in an exhaust line.

According to an embodiment of the present disclosure, an apparatus for processing a substrate includes a processing vessel disposed in a process chamber and including a processing space in which a substrate is accommodated; a liquid supply line configured to process the substrate by supplying processing liquid to the substrate in the processing space; an exhaust line connected to the processing vessel and configured to exhaust gas in the processing space; a spraying portion disposed on the exhaust line and configured to spray cleaning liquid to remove contaminants accumulated in the exhaust line; and a washing liquid discharge line branched from the exhaust line and including a suction portion therein to suction cleaning liquid waste including contaminants removed from the exhaust line by the cleaning liquid and to discharge the cleaning liquid waste to the outside.

The exhaust line may include a plurality of first exhaust pipes connected to a bottom of the processing vessel, a plurality of second exhaust pipes having one ends connected to the corresponding first exhaust pipes, respectively, and the other ends coupled to each other, and a third exhaust pipe connected to a coupling point of the other ends of the second exhaust pipe and through which gaseous contaminants are exhausted, and an inlet end of the washing liquid discharge line is connected to a coupling point of the other ends of the second exhaust pipe.

The spraying portion may be disposed on one end of the second exhaust pipe and sprays cleaning liquid toward the other end of each second exhaust pipe in the second exhaust pipe.

A liquid storage groove configured to be recessed may be disposed on a bottom surface corresponding to the coupling point of the other ends of the second exhaust pipe, and an inlet end of the washing liquid discharge line may extend into the second exhaust pipe and is disposed above the liquid storage groove.

The apparatus may further include a process gas exhaust line having one end connected to the exhaust line and the other end communicating with the process chamber and configured to exhaust atmospheric gas in the process chamber.

The apparatus may further include a processing liquid discharge line configured to discharge processing liquid used for processing the substrate in the processing space to the outside of the process chamber, wherein the processing liquid discharge line and the washing liquid discharge line are connected to each other.

The suction portion may include a vacuum ejector.

The spraying portion may include a cleaning liquid spraying nozzle configured to spray cleaning liquid.

The spraying portion may be disposed such that a direction of spraying the cleaning liquid from the exhaust line may be adjustable to have a predetermined angle toward an exhaust direction.

The apparatus may further include a flow rate measuring device disposed in the exhaust line and configured to measure a flow rate of gas flowing in the exhaust line and a pressure measuring device configured to measure pressure of gas in the exhaust line.

According to another embodiment of the present disclosure, an apparatus for processing a substrate includes a processing vessel disposed in a process chamber and including a processing space in which a substrate is accommodated; a support portion disposed in the processing vessel and configured to rotate and support the substrate; a liquid supply line configured to process the substrate by supplying processing liquid to the substrate in the processing space; a nozzle portion disposed on a discharge end of the liquid supply line and configured to discharge processing liquid; an exhaust line including a plurality of first exhaust pipes connected to a bottom of the processing vessel, a plurality of second exhaust pipes having one ends connected to the corresponding first exhaust pipes, respectively, and the other ends coupled to each other, and a third exhaust pipe connected to a coupling point of the other ends of the second exhaust pipe and configured to exhaust gas in the processing space; a spraying portion disposed on the exhaust line and configured to spray cleaning liquid for removing contaminants accumulated in the exhaust line in an exhaust direction; and a washing liquid discharge line branched from the exhaust line and including an ejector therein to suction cleaning liquid waste including contaminants removed from the exhaust line by the cleaning liquid and to discharge the cleaning liquid waste to the outside.

The spraying portion may be disposed on one end of the second exhaust pipe and sprays cleaning liquid from each second exhaust pipe toward the other end of the second exhaust pipe.

A liquid storage groove configured to be recessed may be disposed on a bottom surface corresponding to a coupling point of the other ends of the second exhaust pipe, and an inlet end of the washing liquid discharge line may extend inwardly and downwardly from an upper end of the second exhaust pipe and may be disposed adjacent to a bottom surface of the liquid storage groove.

The apparatus may further include a process gas exhaust line having one end connected to the exhaust line and the other end communicating with the process chamber and configured to exhaust atmospheric gas in the process chamber.

The apparatus may further include a processing liquid discharge line configured to discharge processing liquid used for processing the substrate in the processing space to the outside of the process chamber, wherein the processing liquid discharge line and the washing liquid discharge line may be connected to each other.

The spraying portion may include a cleaning liquid spraying nozzle configured to spray cleaning liquid.

The spraying portion may include a cleaning liquid spraying nozzle disposed to spray cleaning liquid in a spraying direction having an angle inclined upwardly from the exhaust line in the exhaust direction.

The apparatus may further include a flow rate measuring device disposed in the exhaust line and configured to measure a flow rate of gas flowing in the exhaust line or a pressure measuring device configured to measure pressure of gas in the exhaust line.

The flow rate measuring device or the pressure measuring device may be disposed on least one of one end and the other end of the first exhaust pipe and the second exhaust pipe.

According to another embodiment of the present disclosure, an apparatus for processing a substrate includes a processing vessel disposed in a process chamber and including a processing space in which a substrate is accommodated; a liquid supply line configured to process the substrate by supplying processing liquid to the substrate in the processing space; an exhaust line connected to the processing vessel and configured to exhaust gas in the processing space to the outside; a cleaning liquid spraying nozzle disposed in the exhaust line and configured to spray cleaning liquid to remove contaminants accumulated in the exhaust line toward an exhaust direction; and a washing liquid discharge line branched from the exhaust line disposed downstream of the cleaning liquid spraying nozzle in the exhaust direction, and including a suction portion to suction cleaning liquid waste including contaminants removed from the exhaust line by the cleaning liquid and to discharge the cleaning liquid waste to the outside of the process chamber.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a diagram illustrating an apparatus for processing a substrate according to an embodiment of the present disclosure, viewed from above;

FIG. 2 is a diagram illustrating an apparatus for processing a substrate according to an embodiment of the present disclosure, viewed in a A-A′ direction;

FIG. 3 is a diagram illustrating an apparatus for processing a substrate according to an embodiment of the present disclosure, viewed in a B-B′ direction;

FIG. 4 is a diagram illustrating components of an apparatus for processing a substrate according to an embodiment of the present disclosure;

FIGS. 5A and 5B are cross-sectional diagrams illustrating an apparatus for processing a substrate in which a structure of a first exhaust pipe is different;

FIG. 6 is a diagram illustrating an exhaust line of an apparatus for processing a substrate according to an embodiment of the present disclosure;

FIG. 7 is a cross-sectional diagram illustrating an exhaust line of an apparatus for processing a substrate according to an embodiment of the present disclosure, viewed from above;

FIG. 8 is a cross-sectional diagram illustrating an exhaust line of an apparatus for processing a substrate according to an embodiment of the present disclosure, viewed laterally;

FIG. 9 is a cross-sectional diagram illustrating an exhaust line of an apparatus for processing a substrate according to another embodiment of the present disclosure, viewed laterally;

FIG. 10 is a sectional diagram illustrating a pressure measuring device additionally installed in an exhaust line of an apparatus for processing a substrate according to an embodiment of the present disclosure, viewed laterally;

FIG. 11 is a diagram illustrating components of an apparatus for processing a substrate according to another embodiment of the present disclosure; and

FIG. 12 is a diagram illustrating components of an apparatus for processing a substrate according to another embodiment of the present disclosure.

### DETAILED DESCRIPTION

Hereinafter, embodiments of the present disclosure will be described as below with reference to the attached drawings. The present disclosure may be implemented in different forms and are not limited to the embodiments described herein.

In the drawings, same elements will be indicated by same reference numerals. Also, redundant descriptions and detailed descriptions of known functions and elements that may unnecessarily make the gist of the present disclosure obscure will not be provided. In the drawings, same elements will be indicated by same reference numerals. The terms such as “upper,” “upper portion,” “upper side,” “upper surface,” “upper wall surface,” “lower” “lower portion,” “lower side,” “lower surface,” “lower wall surface” refer to the drawings. Also, the terms such as “internal” and “external are based on a peripheral portion of the component, and may vary depending on the direction in which the element or component may be disposed.

In the embodiment, the term “connected” may not only refer to “directly connected” but also include “indirectly connected” by means of an adhesive layer, or the like. Also, the term “electrically connected” may include both of the case in which elements are “physically connected” and the case in which elements are “not physically connected. The terms, “include,” “comprise,” “is configured to,” or the like of the description are used to indicate the presence of features, numbers, operations, operations, elements, portions or combination thereof, and do not exclude the possibilities of combination or addition of one or more features, numbers, operations, operations, elements, portions or combination thereof.

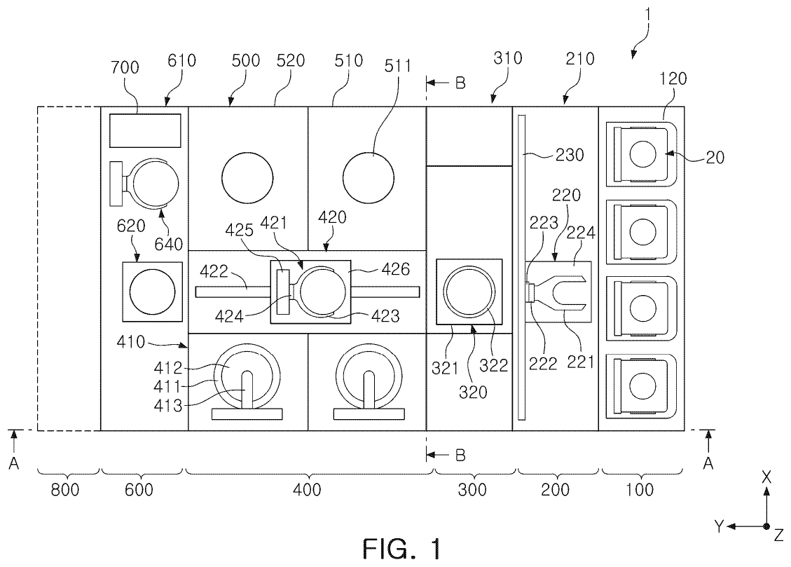

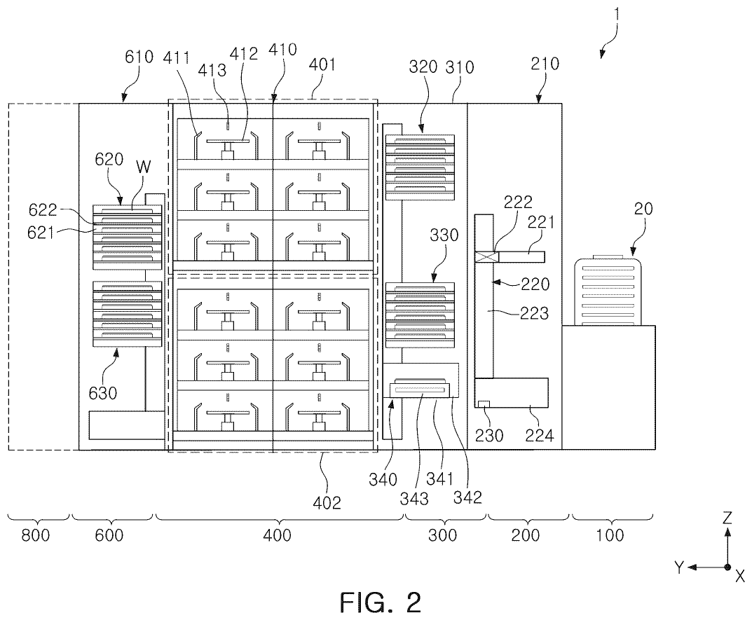

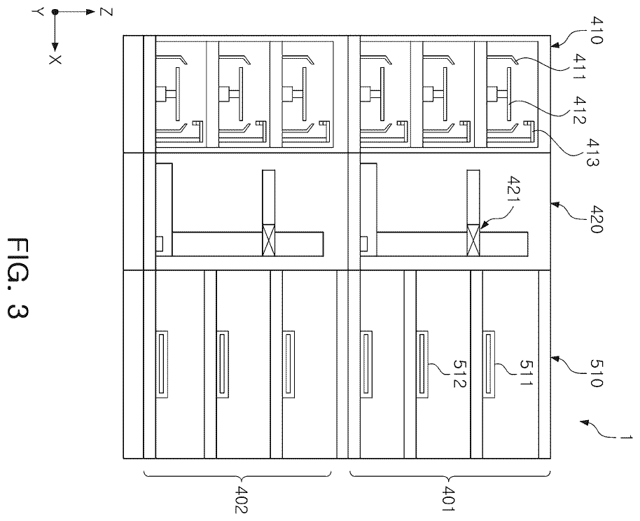

FIG. 1 is a diagram illustrating an apparatus for processing a substrate according to an embodiment, viewed from above. FIG. 2 is a diagram illustrating an apparatus for processing a substrate according to an embodiment, viewed in an A-A′ direction. FIG. 3 is a diagram illustrating an apparatus for processing a substrate according to an embodiment, viewed in a B-B′ direction.

Referring to FIGS. 1 to 3, the apparatus for processing a substrate 1 may include a load port 100, an index module 200, a buffer module 300, a coating and developing module 400, and a purge module 700. The load port 100, the index module 200, the buffer module 300, the coating and developing module 400 and the interface module 600 may be disposed linearly in one direction. The purge module 700 may be provided in the interface module 600. Alternatively, the purge module 700 may be provided in various positions, such as a position in which the exposure apparatus of the rear end of the interface module 600 is connected or a side unit of the interface module 600.

Hereinafter, the direction in which the load port 100, the index module 200, the buffer module 300, the coating and developing module 400, and the interface module 600 are disposed may be referred to as the first direction Y, the direction perpendicular to the first direction Y may be referred to as the second direction X when viewed from above, and the direction perpendicular to the first direction Y and the second direction X may be referred to as the third direction Z.

The substrate W may move in a state accommodated in the cassette 20. The cassette 20 may have a structure sealed from the outside. For example, as the cassette 20, a front open unified pod (FOUP) having a front door may be used.

In the description below, the load port 100, the index module 200, the buffer module 300, the coating and developing module 400, the interface module 600 and the purge module 700 will be described in greater detail.

The load port 100 may have a mounting table 120 on which a cassette 20 containing a substrate W may be disposed. A plurality of mounting tables 120 may be provided, and the mounting tables 120 may be disposed linearly in the second direction X. FIG. 2 illustrates an example in which four mounting tables 120 may be provided, but the number of the mounting tables 120 may be varied.

The index module 200 may transfer the substrate W between the cassette 20 disposed on the mounting table 120 of the load port 100 and the buffer module 300. The index module 200 may include a frame 210, an index robot 220, and a guide rail 230. The frame 210 may be generally provided in the shape of a rectangular parallelepiped having a void therein, and may be disposed between the load port 100 and the buffer module 300. The frame 210 of the index module 200 may be provided on a level lower than that of the frame 310 of the buffer module 300. The index robot 220 and the guide rail 230 may be disposed in the frame 210. The index robot 220 may be provided such that the hand 221 directly handling the substrate W may move and rotate in a first direction Y, a second direction X, and a third direction Z. The index robot 220 may include a hand 221, an arm 222, a support stand 223, and a support 224. The hand 221 may be fixed to the arm 222. The arm 222 may be provided to be stretched and rotated. A length direction of the support stand 223 may be disposed in the third direction Z. The arm 222 may be coupled to the support stand 223 so as to move along the support stand 223. The support stand 223 may be fixed and coupled to the support 224. The guide rail 230 may be provided such that a length direction thereof may be disposed in the second direction X. The support 224 may be coupled to the guide rail 230 so as to linearly move along the guide rail 230. Also, although not illustrated, a door opener for opening and closing the door of the cassette 20 may be further provided in the frame 210.

The buffer module 300 may include a frame 310, a first buffer 320, a second buffer 330 and a cooling chamber 340. The frame 310 may be provided in the shape of a rectangular parallelepiped with a void therein, and may be disposed between the index module 200 and the coating and developing module 400. The first buffer 320, the second buffer 330 and the cooling chamber 340 may be disposed in the frame 310. The cooling chamber 340, the second buffer 330, and the first buffer 320 may be disposed in order in the third direction Z upwardly. The first buffer 320 may be disposed on a level corresponding to a level of the coating module 401 of the coating and developing module 400, and the second buffer 330 and the cooling chamber 340 may be provided on a level corresponding to a level of the developing module 402 of the coating and developing module 400.

Each of the first buffer 320 and the second buffer 330 may temporarily store a plurality of substrates W. The first buffer 320 may have a housing 321 and a plurality of support stands 322. In the first buffer 320, the support stands 322 may be disposed in the housing 321 and may be spaced apart from each other in the third direction Z. The second buffer 330 may have a housing 331 and a plurality of support stands 332. In the second buffer 330, the support stands 332 may be disposed in the housing 331 and may be spaced apart from each other in the third direction Z. The substrate W may be disposed on a support stand 322 of the first buffer 320 and a support stand 332 of the second buffer 330. The housing 331 may have an opening in the direction in which the index robot 220 may be provided such that the index robot 220 may insert or may remove the substrate W from the support stand 332 in the housing 331. The first buffer 320 may have a structure substantially similar to that of the second buffer 330. However, the housing 321 of the first buffer 320 may have an opening in the direction in which the first buffer robot 360 is provided and in the direction in which the coating portion robot 421 disposed on the coating module 401 is provided. The number of support stands 322 provided in the first buffer 320 and the number of support stands 332 provided in the second buffer 330 may be the same or different. According to an example, the number of support stands 332 provided to the second buffer 330 may be greater than the number of support stands 322 provided to the first buffer 320.

The cooling chamber 340 may cool the substrate W. The cooling chamber 340 may include a housing 341 and a cooling plate 342. The cooling plate 342 may have an upper surface on which the substrate W is disposed and the cooling means 343 for cooling the substrate W. As the cooling means 343, various methods such as cooling by cooling water or cooling using a thermoelectric element may be used. Also, a lift pin assembly for positioning the substrate W on the cooling plate 342 may be provided in the cooling chamber 340. The housing 341 may have an opening in the direction in which the index robot 220 is provided and the direction in which the developing portion robot is provided such that the developing portion robot provided in the index robot 220 and developing module 402 may insert or remove the substrate W into or from the cooling plate 342. Also, doors for opening and closing the aforementioned opening may be provided in the cooling chamber 340.

The coating module 401 may include a process of applying a photoresist such as photoresist to the substrate W and a heat treatment process such as heating and cooling the substrate W before and after a resist application process. The coating module 401 may have a coating chamber 410, a heat treatment chamber unit 500, and a transfer chamber 420. The coating chamber 410, the transfer chamber 420, and the heat treatment chamber unit 500 may be disposed in order in the second direction X. That is, with respect to the transfer chamber 420, the coating chamber 410 may be provided on one side of the transfer chamber 420, and the heat treatment chamber unit 500 may be provided on the other side of the transfer chamber 420.

A plurality of coating chambers 410 may be provided in the third direction Z. Also, as illustrated in FIG. 1, a plurality of coating chambers 410 may be provided in the first direction Y, or a coating chamber 410 may be provided in the first direction Y. The heat treatment chamber unit 500 may include a bake chamber 510 and a cooling chamber 520, and the plurality of bake chambers 510 and the plurality of cooling chambers 520 may be provided in the third direction Z. The transfer chamber 420 may be disposed parallel to the first buffer 320 of the first buffer module 300 in the first direction 12. In the transfer chamber 420, a coating portion robot 421 and a guide rail 422 may be disposed. The transfer chamber 420 may have a substantially rectangular shape. The coating portion robot 421 may transfer the substrate W between the bake chamber 510, the cooling chamber 520, the coating chamber 410, and the first buffer 320 of the first buffer module 300.

The guide rail 422 may be disposed such that a length direction thereof may be parallel to the first direction Y. The guide rail 422 may guide the coating portion robot 421 to linearly move in the first direction Y. The coating portion robot 421 may have a hand 423, an arm 424, a support stand 425, and a support 426. The hand 423 may be fixed to the arm 424. The arm 424 may be configured to be stretched such that the hand 423 may move in the horizontal direction. The support stand 425 may be provided such that a length direction thereof may be disposed in the third direction Z. The arm 424 may be coupled to the support stand 425 so as to linearly move in the third direction Z along the support stand 425. The support stand 425 may be fixed and coupled to the support 426, and the support 426 may be coupled to the guide rail 422 so as to move along the guide rail 422.

The coating chambers 410 may have the same structure, but types of processing liquid used in each coating chamber 410 may be different. As the processing liquid, a processing liquid for forming a photoresist film or an anti-reflective film may be used.

The coating chamber 410 may apply processing liquid to the substrate W. A processing unit including a processing vessel 411, a support portion 412 and a nozzle portion 413 may be provided in the coating chamber 410.

For example, in the coating chamber 410, a processing unit may be disposed in the first direction Y, but an embodiment thereof is not limited thereto, and two or more processing units may be disposed in the coating chamber 410. The processing units may have the same structure. However, the type of processing liquid used in the processing units may be different.

The processing vessel 411 of the coating chamber 410 may have an open upper portion shape. The support portion 412 may be disposed in the processing vessel 411 and may support the substrate W. The support portion 412 may be provided to rotate. The nozzle portion 413 may supply processing liquid to the substrate W disposed on the support portion 412. The processing liquid may be applied to the substrate W by a spin coat method. Also, in the coating chamber 410, a nozzle (not illustrated) for supplying a cleaning liquid such as deionized water (DIW) to clean the surface of the substrate W coated with processing liquid and a bag rinse nozzle (not illustrated) for cleaning the lower surface of the substrate W may be optionally further provided.

In the bake chamber 510, when the substrate W is seated by the coating portion robot 421, the substrate W may be heat-treated.

In the bake chamber 510, a prebake process of heating the substrate W to a predetermined temperature to remove organic matter or moisture from the surface of the substrate W before applying the processing liquid or processing liquid to the wafer W, or a soft bake process performed after applying the processing liquid on the wafer W may be performed, and a cooling process for cooling the substrate W may be performed after each heating process.

The bake chamber 510 may include a heating plate 511 and a cooling plate 512. The cooling plate 512 may include a cooling means such as cooling water or a thermoelectric element.

In the cooling chamber 520, a cooling process of cooling the substrate W may be performed before coating the processing liquid. A cooling plate may be provided in the cooling chamber 520. The cooling plate may include a cooling means to which various methods such as cooling by cooling water or cooling using a thermoelectric element may be used to cool the substrate W.

The interface module 600 may connect the coating and developing module 400 to the external exposure apparatus 800. The interface module 600 may include an interface frame 610, a first interface buffer 620, a second interface buffer 630 and a transfer robot 640, and the transfer robot 640 may transfer the substrate transferred to the first and second interface buffers 620 and 630 after the coating and developing module 400 is finished to the exposure apparatus 800. The first and second interface buffer 620 may include a housing 621 and a support stand 622, and the transfer robot 640 and the coating portion robot 421 may insert/out the substrate W to the support stand 622.

The apparatus for processing a substrate having such the components may perform a photo processing process by spraying various types of processing liquid to the substrate. Specifically, in the coating process, solid-state photoresist may be dissolved in solvent and may be supplied in a liquid state to the substrate. During the coating process, the photoresist and solvent may be partially vaporized and may be discharged to the outside through an exhaust pipe formed at the bottom of the processing vessel. Contaminants, including vaporized photoresist and solvent vapor, may be accumulated on the exhaust pipe due as the contaminants is not insufficiently discharged, and when the exhaust pipe is clogged due to the contaminants, the substrate in the processing vessel may be contaminated.

To address the issues above, configurations of the apparatus for processing a substrate according to various embodiments will be described as below.

### Embodiment 1

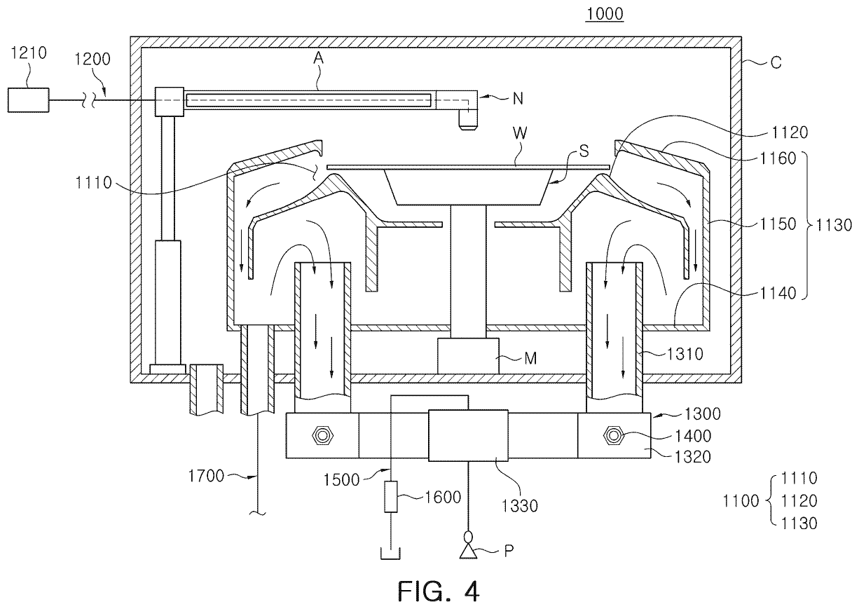

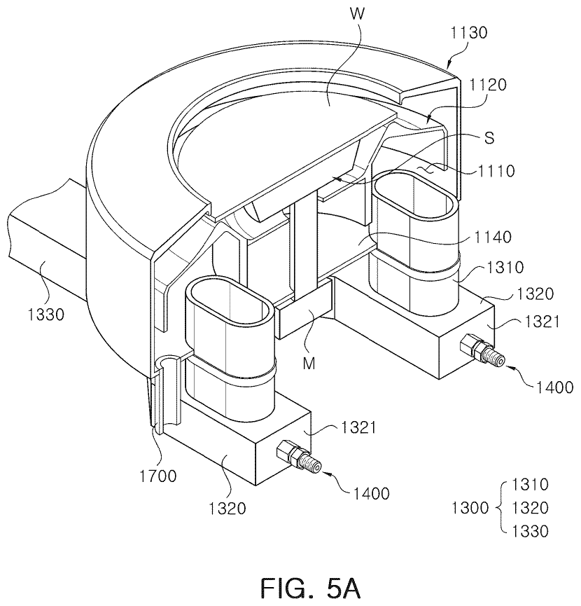

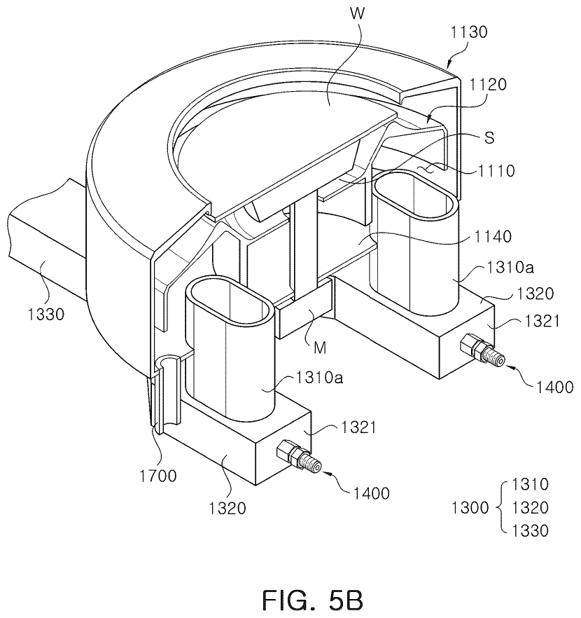

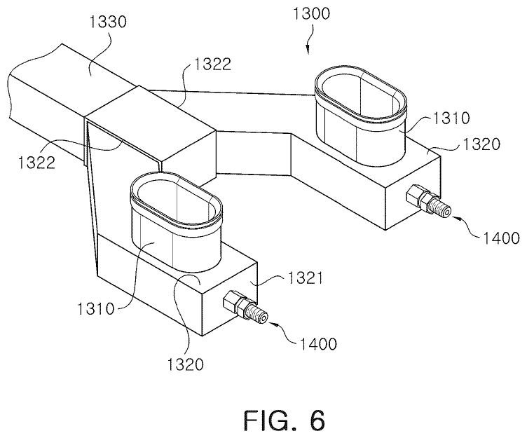

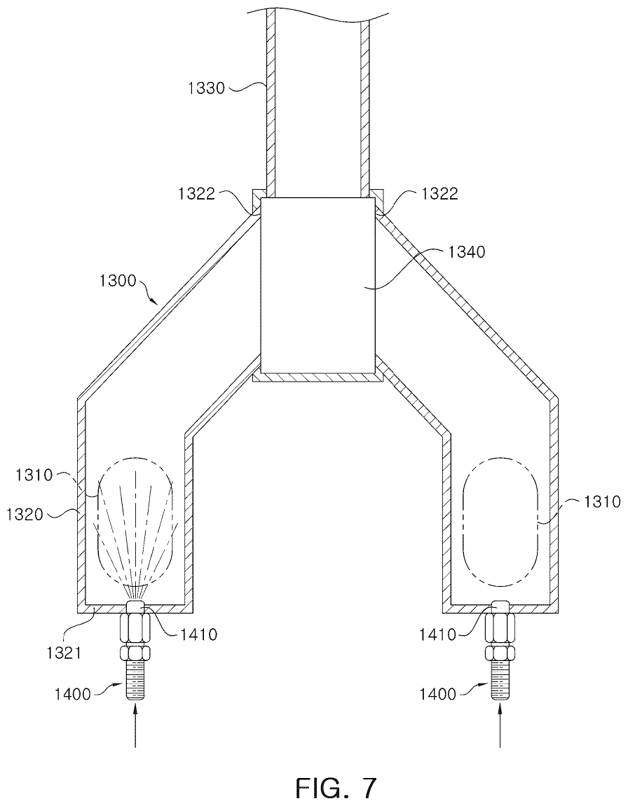

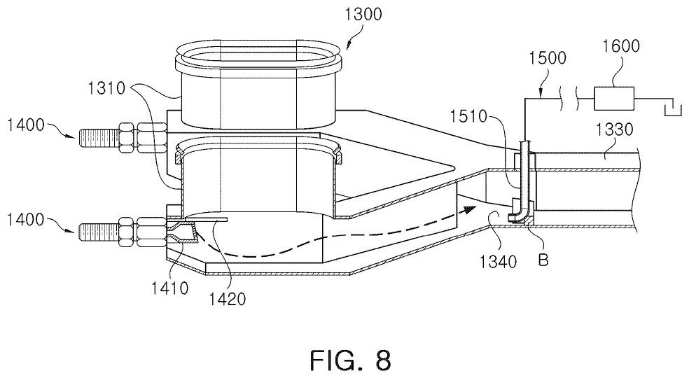

FIG. 4 is a diagram illustrating components of an apparatus for processing a substrate according to an embodiment. FIGS. 5A and 5B are cross-sectional diagrams illustrating an apparatus for processing a substrate in which a structure of a first exhaust pipe is different. FIG. 6 is a diagram illustrating an exhaust line of an apparatus for processing a substrate according to an embodiment. FIG. 7 is a cross-sectional diagram illustrating an exhaust line of an apparatus for processing a substrate according to an embodiment, viewed from above. FIG. 8 is a cross-sectional diagram illustrating an exhaust line of an apparatus for processing a substrate according to an embodiment, viewed laterally.

Referring to FIGS. 4 to 8, the apparatus 1000 for processing a substrate in embodiment 1 may include a processing vessel 1100, a liquid supply line 1200, an exhaust line 1300, a spraying portion 1400 and a washing liquid discharge line 1500.

The processing vessel 1100 may be disposed in a process chamber C and may include a processing space 1110 in which a substrate W is accommodated. When processing liquid is discharged from the liquid supply line 1200, the processing vessel 1100 may receive the liquid splashed from the substrate W and may discharge the liquid externally of the processing vessel 1100. Specifically, the apparatus 1000 for processing a substrate may include a processing liquid discharge line 1700 connected to the processing space 1110 of the processing vessel 1100, and may discharge the processing liquid used for processing the substrate W in the processing space 1110 of the processing vessel 1100 externally of the process chamber C. Here, the process chamber C may be the coating chamber 410 described above. However, an embodiment thereof is not limited thereto, and the process chamber C may be applied to a process chamber in which a process of processing liquid for a substrate, for example, a deposition process, an etching process, a photo process, and a cleaning process is performed.

The processing vessel 1100 may have an open upper portion, for example, a cup shape, and a support portion S for supporting the substrate W may be disposed in the processing space 1110. For example, as illustrated in FIG. 4, the processing vessel 1100 may be disposed on the inner side in the shape of a cup, and may include an inner cup 1120 surrounding the outer side of the support portion S and an outer cup 1130 disposed on the outer side of the inner cup 1120. A hole through which a support axis of the support portion S penetrates may be formed in the central portion of the inner cup 1120. The upper surface external side portion of the inner cup 1120 may be formed to be recessed downwardly toward the outer cup 1130, and the upper surface external side portion of the inner cup 1120 may be provided as a region in which processing liquid and gas may flow. In other words, the flow of gas including contaminants (hereinafter, referred to as fumes) generated during processing liquid and substrate processing may be guided through the space between the inner cup 1120 and the outer cup 1130. The outer cup 1130 may be installed to surround the external side of the support portion S and inner cup 1120 in a cup shape, and may include a bottom surface 1140, a sidewall 1150 and an inclined wall 1160. The bottom surface 1140 of the outer cup 1130 may have a circular plate shape having a hollow shape, and may be connected to a processing liquid discharge line 1700 for discharging processing liquid supplied to the substrate W. The processing liquid discharged by the processing liquid discharge line 1700 may be discarded or reused by an external liquid regeneration system. The sidewall 1150 of the outer cup 1130 may have a circular cylindrical shape surrounding the outside of the support portion S and may extend upwardly in a vertical direction from the edge of the side surface of the bottom surface 1140. The inclined wall 1160 of the outer cup 1130 may extend inwardly from the upper end of the sidewall 1150 in the form of a ring, and the upper end of the inclined wall 1160 may be disposed on a level higher than that of the substrate W supported by the support portion S.

The support portion S may be disposed in the processing vessel 1100 and may support the substrate W. The support portion S may rotate by a driving means such as a motor M. Also, the apparatus 1000 for processing a substrate may support the substrate W to rotate and move up and down in the processing vessel 1100 through the support portion S, such that, when the substrate is processed, the substrate W may be processed by supplying liquid to the substrate W through the liquid supply line 1200 while the substrate W is rotated and supported.

The liquid supply line 1200 may process the substrate W by supplying processing liquid to the substrate W in the processing space 1110 of the processing vessel 1100. Here, various components for processing the liquid before being supplied to the substrate W may be disposed on the liquid supply line 1200. For example, one end of the liquid supply line 1200 may be connected to a processing liquid supply source 1210 such as a tank or bottle, and a nozzle portion N for discharging processing liquid may be disposed on the other end of the liquid supply line 1200, that is, a discharge end for discharging liquid, and also, as a component for filtering processing liquid on the liquid supply line 1200, a filter portion for filtering and removing impurities, charged electric charges, or substances to be removed in the processing liquid if desired, a trap tank for temporarily storing the processing liquid supplied from the processing liquid supply source 1210 and discharging the processing liquid to the outside, a bubble separation portion for separating bubbles in the processing liquid, and a pump for pumping processing liquid at a predetermined pressure and supplying the liquid to the nozzle portion N may be disposed on the liquid supply line 1200.

Here, the nozzle portion N may supply processing liquid to the substrate W disposed on the support portion S. The processing liquid may be a photoresist such as photoresist and may be applied to the substrate W by a spin coat method. The nozzle portion N may be connected to a supply pipe (which may be a portion of a liquid supply line) disposed in the nozzle arm A, may receive processing liquid from the liquid supply line 1200, and may supply the processing liquid to the substrate W. Also, in the process chamber C, for example, a nozzle portion (not illustrated) for supplying cleaning liquid such as deionized water (DIW) to clean the surface of the substrate W coated with processing liquid such as photoresist, and a bag rinse nozzle portion (not illustrated) to clean the lower surface of the substrate W.

The exhaust line 1300 may be connected to the processing vessel 1100 and may exhaust gas in the processing space 1110 to the outside. Here, the gas may include gaseous contaminants (fumes) generated during the process of processing the substrate W in the processing space 1110 of the processing vessel 1100.

The exhaust line 1300 may include a first exhaust pipe 1310, a second exhaust pipe 1320 and a third exhaust pipe 1330. A plurality of the first exhaust pipe 1310 may be provide, may connected to the bottom surface 1140 of the processing vessel 1100, and may be connected to one end 1321 of the second exhaust pipe 1320. As illustrated in FIG. 4, the two first exhaust pipes 1310 may be provided and the first exhaust pipes 1310 may be disposed on the bottom surface 1140 of the processing vessel 1100 disposed on both sides corresponding to each other with respect to the central portion of the processing vessel 1100. Also, the first exhaust pipe 1310 may extend vertically from the bottom of the processing vessel 1100 to the upper and lower portions, and as illustrated in FIG. 5A, the first exhaust pipe 1310 may be configured to be coupled and separated with respect to the bottom of the processing vessel 1100 or as illustrated in FIG. 5B, the first exhaust pipe 1310a may be extended in an integrated manner in the vertical direction from the bottom of the processing vessel 1100 to the upper and lower portions, but an embodiment thereof is not limited thereto. The processing liquid flowing through the space between the inner cup 1120 and the outer cup 1130 of the processing vessel 1100 and gas containing contaminants generated during the processing of substrate W may flow along the exhaust line 1300 through the first exhaust pipe 1310 and may be discharged to the outside. A plurality of the second exhaust pipe 1320 may be provided to correspond to the number of first exhaust pipes 1310, and the second exhaust pipes 1320 may be connected to the first exhaust pipes 1310 corresponding to one end 1321, respectively, and the other ends 1322 may be coupled to each other and may be connected to the third exhaust pipe 1330. The third exhaust pipe 1330 may be connected to the coupling point of the other end 1322 of the second exhaust pipe 1320 such that gaseous contaminants may be exhausted to the outside. Specifically, the third exhaust pipe 1330 may be connected to the pump P, and may exhaust gas, including gaseous contaminants in the processing vessel 1100, to the outside through the exhaust line 1300 including the first exhaust pipe 1310, the second exhaust pipe 1320 and the third exhaust pipe 1330. Also, at least a portion of the second exhaust pipe 1320 and the third exhaust pipe 1330 may extend horizontally.

The spraying portion 1400 may be disposed on the exhaust line 1300 and may spray cleaning liquid to remove contaminants accumulated in the exhaust line 1300. Specifically, the spraying portion 1400 may include a cleaning liquid spraying nozzle 1410. The cleaning liquid spraying nozzle 1410 may spray cleaning liquid. That is, the cleaning liquid spraying nozzle 1410 may include a plurality of spray holes to spray the cleaning liquid, and may be disposed such that a spraying direction in the exhaust line 1300 may be adjustable at a predetermined angle toward the exhaust direction if desired. Also, as illustrated in FIGS. 6 to 8, the cleaning liquid spraying nozzle 1410 of the spraying portion 1400 may be disposed on each one end 1321 of the second exhaust pipe 1320 of the exhaust line 1300, and may be configured to spray cleaning liquid in the second exhaust pipe 1320 toward the other end 1322 of each second exhaust pipe 1320. Also, in the embodiment, the spraying portion 1400 may further include a cover 1420 covering an upper portion of the cleaning liquid spraying nozzle 1410. Specifically, the cleaning liquid spraying nozzle 1410 of the spraying portion 1400 may be disposed to spray the cleaning liquid from the exhaust line 1300 in a spray direction having an upwardly inclined angle toward the exhaust direction. In this case, the cleaning liquid sprayed from the cleaning liquid spraying nozzle 1410 may change the spraying direction thereof by the cover 1420 covering the upper portion of the cleaning liquid spraying nozzle 1410, and fumes accumulated in the exhaust line 1300 may be removed and foreign substances accumulated on the cleaning liquid spraying nozzle 1410 may also be removed, such that a cleaning effect of the cleaning liquid spraying nozzle 1410 may also be realized.

The cleaning liquid sprayed by the cleaning liquid spraying nozzle 1410 may include thinner or acetone. However, an embodiment thereof is not limited to such cleaning liquid and may be applied to any liquid for removing contaminants, that is, fumes, accumulated on the exhaust line.

The cleaning liquid spraying nozzle 1410 of the spraying portion 1400 may periodically perform dummy dispensing in a process standby state to prevent contamination and clogging of the exhaust branch pipe. That is, before or after processing a substrate, dummy dispensing (a substrate is not present in the processing vessel) may be performed, and the cleaning liquid may be sprayed to the exhaust line 1300 through the cleaning liquid spraying nozzle 1410 and fumes accumulated in the exhaust line 1300 or remaining gas not completely exhausted may be discharged to the outside. Also, in the process of automatically cleaning the processing vessel, which performs the operation of cleaning the processing vessel, the spraying portion 1400 may perform an operation of cleaning the internal region of exhaust line 1300 by removing fumes accumulated on the exhaust line 1300 by spraying cleaning liquid. Here, after the cleaning liquid sprayed by the spraying portion 1400 removes the fumes and the fumes are discharged through the washing liquid discharge line 1500, the internal region of the exhaust line may be swiftly dried through the exhaust operation in the exhaust line 1300.

The washing liquid discharge line 1500 may be branched from the exhaust line 1300, and a suction portion 1600 may be disposed therein. The suction portion 1600 may include a vacuum ejector, such that cleaning liquid waste in the exhaust line 1300 may be suctioned and discharged to the outside through the suction portion 1600. That is, cleaning liquid waste containing contaminants removed from the exhaust line 1300 by the cleaning liquid sprayed from the cleaning liquid spraying nozzle 1410 may be suctioned by the suction portion 1600, and may be exhausted externally of the process chamber C.

The inlet end 1510 of the washing liquid discharge line 1500 may be connected to the coupling point of the other end 1322 of the second exhaust pipe 1320 of the exhaust line 1300. Specifically, the inlet end 1510 of the washing liquid discharge line 1500 may extend into the second exhaust pipe 1320 from the upper end of the second exhaust pipe 1320, and may be disposed adjacent to the bottom surface 1340 disposed at the coupling point of the other ends 1322 of the second exhaust pipe 1320. In this case, a protruding block B protruding upwardly may be disposed on the bottom surface 1340 disposed at the coupling point of the other ends 1322 of the second exhaust pipe 1320 to prevent the cleaning liquid sprayed from the cleaning liquid spraying nozzle 1410 from flowing downstream of the third exhaust pipe 1330 in the exhaust direction.

According to the apparatus for processing a substrate having the components, contaminants, that is, fumes generated while processing the substrate W may flow into the first exhaust pipe 1310 of the exhaust line 1300 installed on the bottom surface 1140 of the processing vessel 1100, may pass through the second exhaust pipe 1320, and may be exhausted through the third exhaust pipe 1330. Here, through the cleaning liquid spraying nozzle 1410 installed on one end 1321 of the second exhaust pipe 1320 of the exhaust line 1300, dummy dispensing may be performed periodically or in the standby stage before and after the processing to automatically spray the cleaning liquid, and accordingly, fumes accumulated in the exhaust line 1300 may be effectively removed, clogging of the exhaust line 1300 may be prevented in advance, and contamination of or damage to the substrate W may be effectively prevented. Also, the cleaning liquid waste including the removed fumes may be suctioned to the washing liquid discharge line 1500 by the suction portion 1600 on the washing liquid discharge line 1500 and may be discharged to the outside, such that cleaning liquid waste may be prevented from flowing downstream in the exhaust direction of the exhaust line 1300.

### Embodiment 2

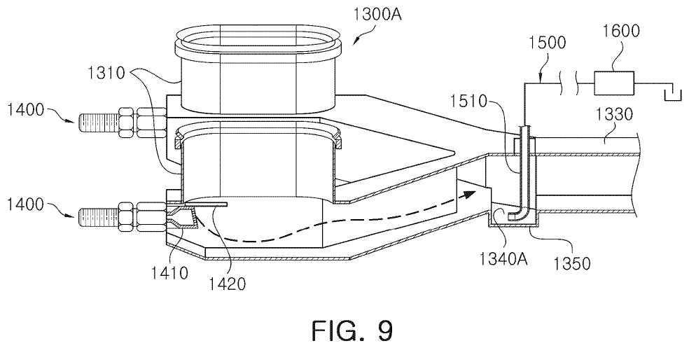

FIG. 9 is a cross-sectional diagram illustrating an exhaust line of an apparatus for processing a substrate according to another embodiment, viewed laterally.

An apparatus for processing a substrate according to embodiment 2 will be described with reference to FIG. 9.

Referring to FIG. 9, the apparatus for processing a substrate according to embodiment 2 may include an exhaust line 1300 including a first exhaust pipe 1310, a second exhaust pipe 1320 and a third exhaust pipe 1330.

As for the apparatus for processing a substrate according to embodiment 2, the components other than the bottom surface 1340A corresponding to the coupling point of the other ends 1322 of the second exhaust pipe 1320 in the exhaust line 1300 may be the same as in embodiment 1, and detailed descriptions of the same components will not be provided to avoid overlapping.

In the apparatus for processing a substrate according to embodiment 2, the exhaust line 1300 may include a first exhaust pipe 1310, a second exhaust pipe 1320 and a third exhaust pipe 1330. Specifically, a liquid storage groove 1350 configured to be recessed may be disposed on the bottom surface 1340A corresponding to the coupling point of the other end 1322 of the second exhaust pipe 1320. In this case, the inlet end 1510 of the washing liquid discharge line 1500 may extend into the second exhaust pipe 1320 and may be disposed above the liquid storage groove 1350. Specifically, the inlet end 1510 of the washing liquid discharge line 1500 may extend downwardly from the upper end of the second exhaust pipe 1320 and may be disposed adjacent to the bottom surface of the liquid storage groove 1350. Due to the configuration of the liquid storage groove 1350, the cleaning liquid sprayed from the cleaning liquid spraying nozzle 1410 may be stored and primarily collected in the liquid storage groove 1350 without the component of the protruding block B described in embodiment 1, may be suctioned to the washing liquid discharge line 1500 by the suction portion 1600 and may discharged to the outside, such that the liquid may be prevented flowing down to the downstream of the third exhaust pipe.

In this embodiment, the recessed liquid storage groove may be disposed on the bottom surface 1340A corresponding to the coupling point of the other ends 1322 of the second exhaust pipe 1320, but an embodiment thereof is not limited thereto. As another example, the bottom surface corresponding to the coupling point of the other end of the second exhaust pipe may be configured as inclined surface or a curved shape sloping upwardly in the exhaust direction.

### Embodiment 3

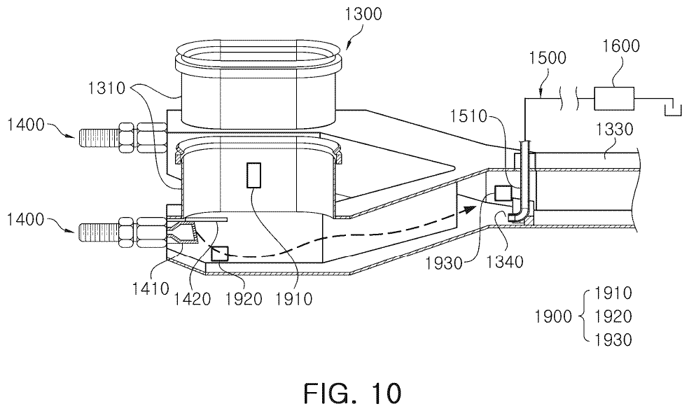

FIG. 10 is a sectional diagram illustrating a pressure measuring device additionally installed in an exhaust line of an apparatus for processing a substrate according to an embodiment, viewed laterally.

Referring to FIG. 10, the apparatus for processing a substrate according to embodiment 3 may include an exhaust line 1300 including a first exhaust pipe 1310, a second exhaust pipe 1320 and a third exhaust pipe 1330 and a pressure measuring device 1900 disposed in the exhaust line 1300.

As for the apparatus for processing a substrate according to embodiment 3, the components other than the pressure measuring device 1900 may be the same as in embodiment 1, and detailed description of the same components will not be provided to avoid overlapping.

In the apparatus for processing a substrate according to embodiment 3, the pressure measuring device 1900 may be disposed on the exhaust line 1300 and may measure the pressure of the gas in the exhaust line 1300 and may identify the degree of contamination of the fumes accumulated in the exhaust line by the measured value. Specifically, when the pressure in the exhaust pipe measured by the pressure measuring device 1900 exceeds a predetermined value, the spraying portion 1400 may be operated to spray the cleaning liquid into the exhaust line 1300, such that a cleaning operation of removing fumes accumulated on the exhaust line 1300 may be performed in time and leakage in the exhaust line may be effectively prevented.

Also, such a pressure measuring device 1900 may be disposed in a portion in which fumes may be easily accumulated in the exhaust line 1300. The pressure measuring device 1900 may be disposed on at least one of the first exhaust pipe 1310, one end 1321 and the other end 1322 of the second exhaust pipe 1320 of the exhaust line 1300. Specifically, referring to FIG. 10, the pressure measuring device 1900 may include a first pressure measuring device 1910 disposed in the first exhaust pipe, a second pressure measuring device 1920 disposed on one end 1321 of the second exhaust pipe 1320, and a third pressure measuring device 1930 disposed at the coupling point of the other ends 1322 of the second exhaust pipe 1320 and may identify the degree of contamination of the fumes accumulated in each position.

In the above embodiment 3, the pressure measuring device for measuring the pressure of the gas in the exhaust line has been described as an example, but an embodiment thereof is not limited thereto, and the degree of contamination of the fumes accumulated in the exhaust line may be identified in various manners. For example, when the flow rate of the gas in the exhaust line measured using a flow rate measuring device disposed in the exhaust line and measuring the flow rate of the gas flowing in the exhaust line exceeds a predetermined value, the cleaning liquid may be sprayed into the exhaust line by operating the spraying portion, such that a cleaning operation of removing the fumes accumulated in the exhaust line may be performed in time, and leakage in the exhaust line may be effectively prevented.

### Embodiment 4

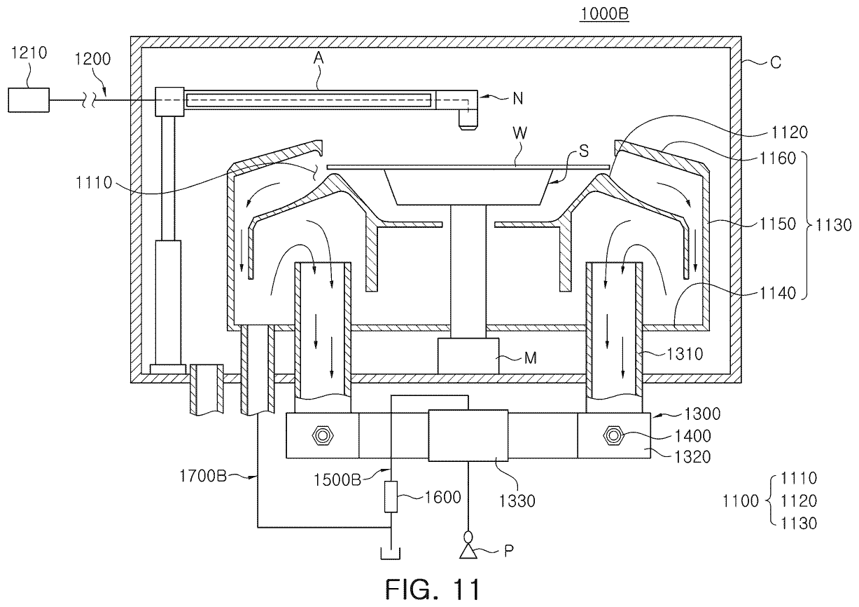

FIG. 11 is a diagram illustrating components of an apparatus for processing a substrate according to another embodiment.

Referring to FIG. 11, an apparatus 1000B for processing a substrate according to embodiment 4 may include a processing vessel 1100, a liquid supply line 1200, an exhaust line 1300, a spraying portion 1400, a washing liquid discharge line 1500B, a suction portion 1600 and a processing liquid discharge line 1700B.

As for the apparatus for processing a substrate 1000B according to embodiment 4, the components other than the washing liquid discharge line 1500B and the processing liquid discharge line 1700B may be the same as in embodiment 1, and a detailed description of the same components will not be provided to avoid overlapping.

The washing liquid discharge line 1500B may be branched from the exhaust line 1300, and a suction portion 1600 may be disposed therein. The suction portion 1600 may include a vacuum ejector, and may suction cleaning liquid waste in the exhaust line 1300 through the suction portion 1600 and may discharge the cleaning liquid waste to the outside.

The processing liquid discharge line 1700B may be connected to the processing space 1110 of the processing vessel 1100 and may discharge the processing liquid used to process the substrate W in the processing space 1110 of the processing vessel 1100 to the outside of the process chamber C.

In this embodiment, the washing liquid discharge line 1500B and the processing liquid discharge line 1700B may be connected to each other. That is, downstream of the washing liquid discharge line 1500B and the processing liquid discharge line 1700B may be coupled to each other and may discharge cleaning liquid waste and processing liquid waste to the outside using a discharge line. Here, cleaning liquid waste and processing liquid waste discharged by the washing liquid discharge line 1500B and the processing liquid discharge line 1700B may be discarded or may be reused by an external liquid recovery system.

### Modified Embodiment of Embodiment 4

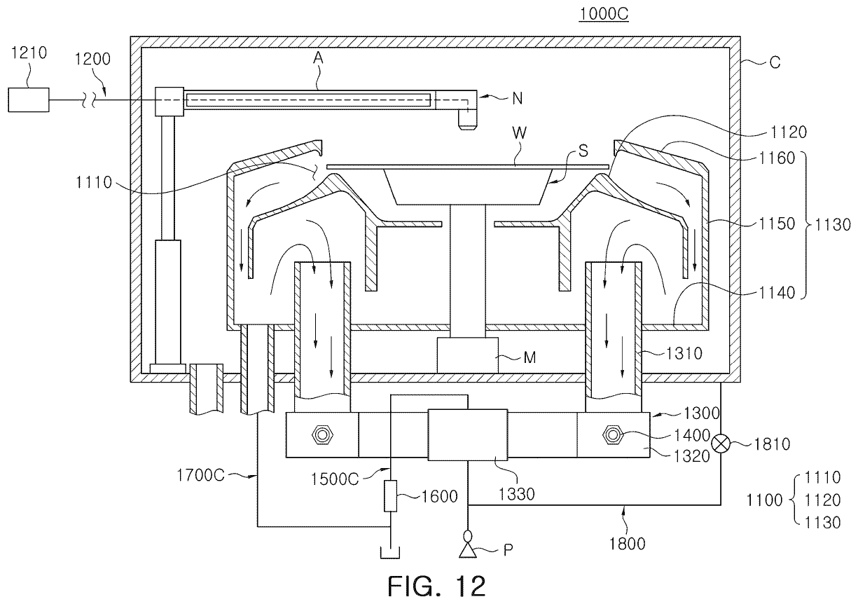

FIG. 12 is a diagram illustrating components of an apparatus for processing a substrate according to another embodiment.

Referring to FIG. 12, the apparatus 1000C for processing a substrate according to the modified embodiment of embodiment 4 may include a processing vessel 1100, a liquid supply line 1200, an exhaust line 1300, a spraying portion 1400, a washing liquid discharge line 1500C, a suction portion 1600, a processing liquid discharge line 1700C and a process gas exhaust line 1800.

As for the apparatus 1000C for processing a substrate according to the modified embodiment of embodiment 4, the components other than the process gas exhaust line 1800 may be the same as in embodiment 1, and thus, a detailed description thereof will not be provided to avoid overlapping.

In the modified embodiment, the washing liquid discharge line 1500C and the processing liquid discharge line 1700C may be the same as the washing liquid discharge line 1500B and the processing liquid discharge line 1700B in embodiment 4, and thus, a detailed description thereof will not be provided.

In the apparatus for processing a substrate 1000C according to the modified embodiment of embodiment 4, one end of the process gas exhaust line 1800 may be connected to the exhaust line 1300 and the other end may be connected to the process chamber C to exhaust atmospheric gas in the process chamber C. Here, specifically, the process gas exhaust line 1800 may be connected to the downstream of the process gas exhaust line 1800 and the downstream of the third exhaust pipe 1330 of the exhaust line 1300. That is, the downstream of the third exhaust pipe 1330 and the downstream of the process gas exhaust line 1800 may be coupled to each other, and gas and process gas including contaminants may be discharged to the outside using a single exhaust line. Here, a shut-off valve 1810 for opening and closing the discharge of process gas in the process chamber C may be disposed in the process gas exhaust line 1800, such that the process gas in the process chamber C may be discharged to the outside through the shut-off valve 1810 such that the pressure or process conditions in the process chamber C may reach a predetermined range.

Accordingly, according to the configuration of the apparatus for processing a substrate according to the embodiment, contaminants, that is, fumes generated while processing the substrate may flow into the first exhaust pipe of the exhaust line installed on the bottom of the processing vessel, may pass through the second exhaust pipe and may be exhausted to the outside through the third exhaust pipe. By spraying the cleaning liquid through the spraying portion installed at one end of the second exhaust pipe of the exhaust line, the fumes accumulated inside the exhaust line may be effectively removed, clogging of the exhaust line may be prevented in advance, and contamination or damage to the substrate may be effectively prevented. Also, the cleaning liquid waste including the removed fumes may be suctioned into the washing liquid discharge line by the suction portion on the washing liquid discharge line and may be discharged to the outside, such that the cleaning liquid waste may be effectively prevented from flowing downstream in the exhaust direction of the exhaust line.

In the embodiments, the suction portion may include a vacuum ejector, but an embodiment thereof is not limited thereto, and may have various suction structure as long as the cleaning liquid waste in the exhaust line may be suctioned and discharged to the outside. For example, suction cleaning liquid waste in the exhaust line may be suctioned by a pressure difference in the suction portion using driving liquid as a driving source.

In the embodiments, the apparatus for processing a substrate may be applied to a coating chamber, but an embodiment thereof is not limited thereto, and various chambers of an apparatus for processing a substrate may be applied, for example, a developing chamber of a coating and developing module, or an interface module may be applied.

In the embodiments, the exhaust line may include a first exhaust pipe, a second exhaust pipe and a third exhaust pipe, but an embodiment thereof is not limited thereto and may be varied, and also, a processing vessel may be connected to the exhaust line, but an embodiment thereof is not limited thereto, and a plurality of processing vessels may be connected to the exhaust line depending on the number of processing vessels disposed in the process chamber, and in this case, as a specific example, a first exhaust pipe and a second exhaust pipe may be configured as a branch pipe group, and the branch pipe group may be disposed to correspond to the number of processing vessels, and the branch pipe groups may be connected to a third exhaust pipe and may perform discharging.

According to the aforementioned embodiments, in the apparatus for processing a substrate, contaminants, or fumes, generated during substrate processing may flow into the first exhaust pipe of the exhaust line installed at the bottom of the processing vessel, may pass through the second exhaust pipe, and may be exhausted to the outside through the third exhaust pipe. By spraying the cleaning liquid through the spraying portion installed on one end of the second exhaust pipe of the line, fumes accumulated in the exhaust line may be effectively removed, clogging of the exhaust line may be prevented in advance, and contamination of or damage to the substrate may be effectively prevented. Also, the cleaning liquid waste including the removed fumes may be suctioned into the washing liquid discharge line by the suction portion on the washing liquid discharge line and may be discharged to the outside, such that the cleaning liquid waste may be effectively prevented from flowing downstream in the exhaust direction of the exhaust line.

While the embodiments have been illustrated and described above, it will be apparent to those skilled in the art that modifications and variations could be made without departing from the scope of the present disclosure as defined by the appended claims.

What is claimed is:

1. An apparatus for processing a substrate, the apparatus comprising:
a processing vessel disposed in a process chamber and including a processing space in which a substrate is accommodated;
a liquid supply line configured to process the substrate by supplying processing liquid to the substrate in the processing space;
an exhaust line connected to the processing vessel and configured to exhaust gas in the processing space;
a spraying portion disposed on the exhaust line and configured to spray cleaning liquid to remove contaminants accumulated in the exhaust line; and
a washing liquid discharge line branched from the exhaust line and including a suction portion therein to suction cleaning liquid waste including contaminants removed from the exhaust line by the cleaning liquid and to discharge the cleaning liquid waste to the outside.

2. The apparatus of claim 1,
wherein the exhaust line includes a plurality of first exhaust pipes connected to a bottom of the processing vessel, a plurality of second exhaust pipes having one ends connected to the corresponding first exhaust pipes, respectively, and the other ends coupled to each other, and a third exhaust pipe connected to a coupling point of the other ends of the second exhaust pipe and through which gaseous contaminants are exhausted, and
wherein an inlet end of the washing liquid discharge line is connected to a coupling point of the other ends of the second exhaust pipe.

3. The apparatus of claim 2, wherein the spraying portion is disposed on one end of the second exhaust pipe and sprays cleaning liquid toward the other end of each second exhaust pipe in the second exhaust pipe.

4. The apparatus of claim 2, wherein a liquid storage groove configured to be recessed is disposed on a bottom surface corresponding to the coupling point of the other ends of the second exhaust pipe, and an inlet end of the washing liquid discharge line extends into the second exhaust pipe and is disposed above the liquid storage groove.

5. The apparatus of claim 1, further comprising:
a process gas exhaust line having one end connected to the exhaust line and the other end communicating with the process chamber and configured to exhaust atmospheric gas in the process chamber.

6. The apparatus of claim 1, further comprising:
a processing liquid discharge line configured to discharge processing liquid used for processing the substrate in the processing space to the outside of the process chamber,
wherein the processing liquid discharge line and the washing liquid discharge line are connected to each other.

7. The apparatus of claim 1, wherein the suction portion includes a vacuum ejector.

8. The apparatus of claim 1, wherein the spraying portion includes a cleaning liquid spraying nozzle configured to spray cleaning liquid.

9. The apparatus of claim 1, wherein the spraying portion is disposed such that a direction of spraying the cleaning liquid from the exhaust line is adjustable to have a predetermined angle toward an exhaust direction.

10. The apparatus of claim 1, further comprising:
a flow rate measuring device disposed in the exhaust line and configured to measure a flow rate of gas flowing in the exhaust line and a pressure measuring device configured to measure pressure of gas in the exhaust line.

11. An apparatus for processing a substrate, the apparatus comprising:
a processing vessel disposed in a process chamber and including a processing space in which a substrate is accommodated;
a support portion disposed in the processing vessel and configured to rotate and support the substrate;
a liquid supply line configured to process the substrate by supplying processing liquid to the substrate in the processing space;
a nozzle portion disposed on a discharge end of the liquid supply line and configured to discharge processing liquid;
an exhaust line including a plurality of first exhaust pipes connected to a bottom of the processing vessel, a plurality of second exhaust pipes having one ends connected to the corresponding first exhaust pipes, respectively, and the other ends coupled to each other, and a third exhaust pipe connected to a coupling point of the other ends of the second exhaust pipe and configured to exhaust gas in the processing space;
a spraying portion disposed on the exhaust line and configured to spray cleaning liquid for removing contaminants accumulated in the exhaust line in an exhaust direction; and
a washing liquid discharge line branched from the exhaust line and including an ejector therein to suction cleaning liquid waste including contaminants removed from the exhaust line by the cleaning liquid and to discharge the cleaning liquid waste to the outside.

12. The apparatus of claim 11, wherein the spraying portion is disposed on one end of the second exhaust pipe and sprays cleaning liquid from each second exhaust pipe toward the other end of the second exhaust pipe.

13. The apparatus of claim 11, wherein a liquid storage groove configured to be recessed is disposed on a bottom surface corresponding to a coupling point of the other ends of the second exhaust pipe, and an inlet end of the washing liquid discharge line extends inwardly and downwardly from an upper end of the second exhaust pipe and is disposed adjacent to a bottom surface of the liquid storage groove.

14. The apparatus of claim 11, further comprising:
a process gas exhaust line having one end connected to the exhaust line and the other end communicating with the process chamber and configured to exhaust atmospheric gas in the process chamber.

15. The apparatus of claim 11, further comprising:
a processing liquid discharge line configured to discharge processing liquid used for processing the substrate in the processing space to the outside of the process chamber,
wherein the processing liquid discharge line and the washing liquid discharge line are connected to each other.

16. The apparatus of claim 11, wherein the spraying portion includes a cleaning liquid spraying nozzle configured to spray cleaning liquid.

17. The apparatus of claim 11, wherein the spraying portion includes a cleaning liquid spraying nozzle disposed to spray cleaning liquid in a spraying direction having an angle inclined upwardly from the exhaust line in the exhaust direction.

18. The apparatus of claim 11, further comprising:
a flow rate measuring device disposed in the exhaust line and configured to measure a flow rate of gas flowing in the exhaust line or a pressure measuring device configured to measure pressure of gas in the exhaust line.

19. The apparatus of claim 18, wherein the flow rate measuring device or the pressure measuring device is disposed on least one of one end and the other end of the first exhaust pipe and the second exhaust pipe.

20. An apparatus for processing a substrate, the apparatus comprising:
a processing vessel disposed in a process chamber and including a processing space in which a substrate is accommodated;
a liquid supply line configured to process the substrate by supplying processing liquid to the substrate in the processing space;
an exhaust line connected to the processing vessel and configured to exhaust gas in the processing space to the outside;
a cleaning liquid spraying nozzle disposed in the exhaust line and configured to spray cleaning liquid to remove contaminants accumulated in the exhaust line toward an exhaust direction; and
a washing liquid discharge line branched from the exhaust line disposed downstream of the cleaning liquid spraying nozzle in the exhaust direction, and including a suction portion to suction cleaning liquid waste including contaminants removed from the exhaust line by the cleaning liquid and to discharge the cleaning liquid waste to the outside of the process chamber.
